(19) United States
(12) Patent Application Publication
(10) Pub. No.: US 2018/0048120 A1
(43) Pub. Date: Feb. 15, 2018

(54) SEMICONDUCTOR LIGHT EMITTING DEVICE

(71) Applicant: KABUSHIKI KAISHA TOSHIBA, Minato-ku (JP)

(72) Inventors: Haruhiko YOSHIDA, Funabashi (JP); Kazuya OHIRA, Tokyo (JP); Hirotaka UEMURA, Kawasaki (JP); Norio llZUKA, Kawasaki (JP)

(73) Assignee: KABUSHIKI KAISHA TOSHIBA, Minato-ku (JP)

(21) Appl. No.: 15/445,378

(22) Filed: Feb. 28, 2017

(30) Foreign Application Priority Data
Aug. 15, 2016 (JP) 2016-159287

(51) Int. Cl. H01S 5/183; H01S 5/343; H01S 5/02; H01S 5/042; H01S 5/026

(52) U.S. Cl. CPC H01S 5/18361; H01S 5/0425; H01S 5/026; H01S 5/021; H01S 5/34326; H01S 5/3434; H01S 5/18375

(57) ABSTRACT

According to one embodiment, a semiconductor light emitting device includes a substrate, a semiconductor light emitting structure including an active layer, a first light reflecting structure disposed between the substrate and the semiconductor light emitting structure, a second light reflecting structure disposed on an upper side of the semiconductor light emitting structure and a pair of electrodes applying a current to the semiconductor light emitting structure. At least one of the first and second light reflecting structures is a multilayer reflective film including a plurality of structure layers, each structure layer including a high refractive index region and a low refractive index region which are disposed such that a refractive index of the structure layer is periodically changed, and a low refractive index layer disposed between two adjacent structure layers.

### CROSS-REFERENCE TO RELATED APPLICATIONS

This application is based upon and claims the benefit of priority from Japanese Patent Application No. 2016-159287, filed Aug. 15, 2016, the entire contents of which are incorporated herein by reference.

### FIELD

Embodiments described herein relate generally to a semiconductor light emitting device and a multilayer reflective film.

### BACKGROUND

In recent years, there has been increasing demand for transmitting a large capacity data between substrates, and an optical wiring (optical link) such as an optical fiber has been put into practical use in place of an electric wire such as a cable.

The optical link is configured to include a semiconductor light emitting device and a semiconductor light receiving device. As the semiconductor light emitting device, a vertical-cavity surface-emitting laser (VCSEL) device is generally used. The VCSEL has a structure in which a semiconductor layer including an active layer (light emitting layer) is interposed between two reflectors. The reflector is, for example, a distributed Bragg reflector (hereinafter, referred to as DER). In the VCSEL equipped with the DBR, the DBR must be constituted by a laminate of several tens of layers stacked one upon the other in order to obtain a high reflectance required for laser oscillation, and the thickness of the VCSEL comes to be about several micrometers.

On the other hand, the semiconductor light receiving device used for the optical link can be configured without the laminate of several tens of layers such as the DBR. The semiconductor light receiving device is greatly different in the layer structure, and thus it is difficult to simultaneously integrate the semiconductor light emitting device and the semiconductor light receiving device used for the optical link.

### BRIEF DESCRIPTION OF THE DRAWINGS

FIG. 1 is a schematic cross-sectional view of a semiconductor light emitting device according to a first embodiment.

FIGS. 2A, 2B, 2C, 2D, 2E, 2F, 2G, 2H, 2I, 2J, 2K and 2L are schematic cross-sectional views for describing an exemplary method of manufacturing the semiconductor light emitting device according to the first embodiment.

FIG. 3 is a schematic cross-sectional view of a semiconductor light emitting device according to a second embodiment.

FIG. 4 is a diagram illustrating a reflectance of light and a wavelength range of a reflected light obtained by a finite difference time domain simulation in a reflective film of an experimental example. FIGS. 5A, 5B, 5C, 5D and 5E are schematic cross-sectional views for describing an example of a method of manufacturing a semiconductor light receiving device.

### DETAILED DESCRIPTION

In general, according to one embodiment, there is provided a semiconductor light emitting device comprising a substrate, a semiconductor light emitting structure including an active layer, a first light reflecting structure disposed between the substrate and the semiconductor light emitting structure, a second light reflecting structure disposed on the upper side of the semiconductor light emitting structure, and a pair of electrodes which apply an electric current to the semiconductor light emitting structure. At least one of the first light reflecting structure and the second light reflecting structure is a multilayer reflective film including a plurality of structure layers, each structure layer including a high refractive index region and a low refractive index region which are disposed such that a refractive index of the structure layer is periodically changed, and a low refractive index layer disposed between two adjacent structure.

Some embodiments will be described below referring to the accompanying drawings. In order to better clarify the description, drawings may more roughly show the width, thickness, shape, etc., of each element than in an actual embodiment. However, these drawings are just examples and do not limit the interpretation of the present invention. In the description and drawings, structural elements having the same or similar functions are denoted by the same reference numbers, and duplication of description thereof may be omitted.

A semiconductor light emitting device according to one embodiment comprises a substrate, a semiconductor light emitting structure including an active layer, a first light reflecting structure disposed between the substrate and the semiconductor light emitting structure, a second light reflecting structure disposed on the upper side of the semiconductor light emitting structure, and a pair of electrodes which apply an electric current to the semiconductor light emitting structure. At least one of the first light reflecting structure and the second light reflecting structure is a multilayer reflective film including a plurality of structure layers, each structure layer including a high refractive index region and a low refractive index region which are disposed such that a refractive index of the structure layer is periodically changed, and a low refractive index layer disposed between two adjacent structure.

In one or more embodiments, a thickness d of the low refractive index layer, a refractive index n of the low refractive index layer, and an emission wavelength λ of the semiconductor light emitting device satisfy the following relation:

d<(¼n)·λ (1).

In one or more embodiments, a thickness d of the low refractive index layer, a refractive index n of the low refractive index layer, and an emission wavelength λ of the semiconductor light emitting device satisfy the following relation:

exp(−2πnd/λ)<0.5 (2).

In one or more embodiments, the device further comprises a first dielectric layer that is formed between the substrate and the first light reflecting structure, and/or a second dielectric layer that is formed between the second light reflecting structure and the electrode.

In one or more embodiments, the second light reflecting structure includes a metal layer that serves as one of the pair of electrodes.

In one or more embodiments, the plurality of structure layers are different in thickness from each other.

In one or more embodiments, the low refractive index region is made of silicon oxide or air, and the high refractive index region is made of silicon.

In one or more embodiments, the low refractive index layer is made of silicon oxide.

In one or more embodiments, the structure layer is configured by a photonic crystal.

In one or more embodiments, the first light reflecting structure consists of a single-layer reflective film that is configured by one structure layer, the second light reflecting structure consists of the multilayer reflective film, and the structure layer is configured by the high refractive index region and the low refractive index region that are disposed such that the refractive index is periodically changed.

In one or more embodiments, the semiconductor light emitting structure comprises a group III-V compound semiconductor.

In one or more embodiments, the substrate is formed of a semiconductor material having a band-gap energy larger than that of a semiconductor material forming the active layer.

In one or more embodiments, the substrate is a dissimilar substrate formed by a semiconductor material which is dissimilar to the semiconductor material forming the semiconductor light emitting structure.

In one or more embodiments, the substrate is a silicon substrate.

In one or more embodiments, the first light reflecting structure is surrounded by a semiconductor which is formed on the substrate and similar in kind to that of the substrate, and a surface of the first light reflecting structure is included in a plane including the surface of the similar substrate or is placed below the plane.

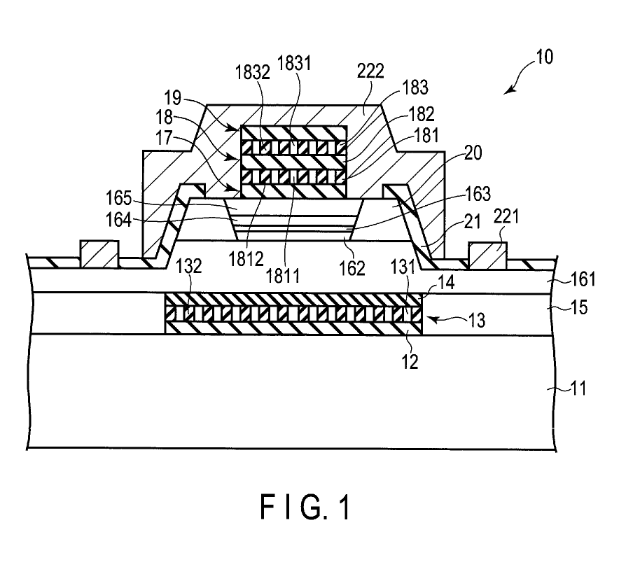

FIG. 1 schematically illustrates a semiconductor light emitting device 10 according to a first embodiment. The semiconductor light emitting device 10 is a vertical-cavity surface-emitting laser (VCSEL) device in which a second light reflecting structure comprises a multilayer reflective film.

As illustrated in FIG. 1, the semiconductor light emitting device 10 includes a substrate 11. The substrate 11 may be a similar substrate formed of a semiconductor material which is similar in kind to that of a semiconductor light emitting structure including an active layer (that is, a light emitting layer) formed thereon, or may be a dissimilar substrate (for example, a silicon substrate in a case where the semiconductor of the semiconductor light emitting structure including the active layer is a group III-V or group II-VI compound semiconductor) which is formed of a semiconductor material which is dissimilar in kind to that of the semiconductor of the semiconductor light emitting structure. Examples of the substrate 11 include silicon, InP, GaAs, GaN, and sapphire substrates.

A first light reflecting structure 13 is provided on the substrate 11 through a dielectric layer (for example, silicon oxide layer) 12. The first light reflecting structure 13 is configured by a structure layer whose refractive index is periodically changed. The structure layer 13 is configured by a high refractive index region which has a relatively-high refractive index, and a low refractive index region which has a relatively-low refractive index, both of which are periodically disposed two-dimensionally. More specifically, the structure layer 13 may be configured by a photonic crystal thin film. In other words, the structure layer 13 includes a high refractive index layer made of a high refractive index material as a base material, and a dielectric material having a refractive index lower than that of the base material is buried at a constant interval in the base material. Examples of the base material include amorphous silicon, InP, GaAs, AlGaAs, GaN, and AlGaN, and examples of the dielectric material include an oxide, a nitride, or an oxynitride of silicon, gallium, aluminum, and indium. In FIG. 1, in the amorphous silicon forming a base material 131, a plurality of holes are formed at a constant interval in an in-plane direction, and a dielectric material 132 fills the holes in the amorphous silicon layer 131. Alternatively, the air may be used in place of the dielectric material 132.

A low refractive index layer 14 is provided on the structure layer 13. The low refractive index layer 14 may be formed of a dielectric material or a transparent electrode material. Examples of the dielectric material include an oxide, a nitride, or an oxynitride of silicon, gallium, aluminum, and indium. Examples of the transparent electrode material include indium titanium oxide (ITiO) and indium tin oxide (ITO). A semiconductor layer (hereinafter, referred to as similar semiconductor layer) 15 made of a semiconductor material similar in kind to that of the substrate 11 is disposed surrounding the dielectric layer 12, and the structure layer 13 and the low refractive index layer 14 which form the first light reflecting structure 13.

For example, in a case where the substrate 11 is a silicon substrate, the semiconductor layer 15 may be formed of silicon. The structure layer 13 may be disposed such that the surface thereof is included in the plane including the similar semiconductor layer 15, or may be buried within the similar semiconductor layer 15. Alternatively, the dielectric layer 12, and the structure layer 13 and the low refractive index layer 14 which form the structure layer 13 may be made by forming recess corresponding the layers 12, 13 and 14, respectively, in the substrate 11, and forming the layers in the recesses. In such a case, the surface of the structure layer 13 can be placed below the surface of the substrate 11. By such an arrangement of the dielectric layer 12, and the structure layer 13 and the low refractive index layer 14 which form the first light reflecting structure, a stress applied onto a semiconductor light emitting structure 16, described in detail below, formed on the upper side of the dielectric layer 12, and the structure layer 13 and the low refractive index layer 14 which form the first light reflecting structure is alleviated. Thus, interfacial peeling does not occur at the interface between the low refractive index layer 14 and the semiconductor light emitting structure 16. Even in a case where the device is subjected to an environmental temperature change or a temperature cycle, the characteristics of the device can be maintained stably, and a high reliability can be secured.

On the similar semiconductor layer 15 including the surface of the low refractive index layer 14, there is provided the semiconductor light emitting structure 16 which includes a first clad layer 161 of a first conductivity type also serving as a first contact layer of the first conductivity type, a first light confinement layer 162 of the first conductivity type, an active layer 163, a second light confinement layer 164 of a second conductivity type, and a second clad layer 165 of the second conductivity type. Herein, the first conductivity type and the second conductivity type are opposite conductivity types to each other. If one of conductivity types is a p type, the other conductivity type is n type, and on the contrary if one of conductivity types is n type, the other conductivity type is p type. It is desirable that the first clad layer 161 and the second clad layer 165 be formed of InP of n or p type.

A low refractive index layer 17 is provided on the semiconductor light emitting structure 16. The low refractive index layer 17 may be formed of a dielectric material or a transparent electrode material. Examples of the dielectric material include an oxide, a nitride, or an oxynitride of silicon, gallium, aluminum, and indium. Examples of the transparent electrode material include indium titanium oxide (ITiO) and indium tin oxide (ITO).

On the semiconductor light emitting structure 16, there is provided a second light reflecting structure through the low refractive index layer 17. The second light reflecting structure is constituted by a multilayer reflective film 18 in this embodiment.

In general, the multilayer reflective film forming the second light reflecting structure includes a plurality of structure layers (in FIG. 1, two structure layers 181 and 183 forming the multilayer reflective film 18) which are disposed apart from each other and periodically changed in the refractive index. Each of the plurality of structure layers included in the multilayer reflective film can be configured similarly to the structure layer 13 forming the first light reflecting structure. In other words, each of the structure layers forming the second light reflecting structure is configured by a high refractive index region which has a relatively-high refractive index and a low refractive index region which has a relatively-low refractive index, both of which are periodically disposed two-dimensionally. The structure layers each can be configured by a photonic crystal thin film. In other words, each of the structure layers includes high refractive index layer made of a high refractive index material as a base material, and a dielectric material having a refractive index lower than that of the base material is buried at a constant interval in the base material. Examples of the base material include amorphous silicon, InP, GaAs, AlGaAs, GaN, and AlGaN, and examples of the dielectric material include an oxide, a nitride, or an oxynitride of silicon, gallium, aluminum, and indium. In FIG. 1, in the amorphous silicon forming a base material 1811, a plurality of holes are formed at a constant interval in an in-plane direction, and a dielectric material 1812 fills the holes in the amorphous silicon layer 1811. Likewise, the structure layer 183 includes a high refractive index layer made of a high refractive index material as a base material, and a dielectric material having a refractive index lower than that of the base material is buried at a constant interval in the base material. Examples of the base material include amorphous silicon, InP, GaAs, AlGaAs, GaN, and AlGaN, and examples of the dielectric material include an oxide, a nitride, or an oxynitride of silicon, gallium, aluminum, and indium. In FIG. 1, in the amorphous silicon forming a base material 1831, a plurality of holes are formed at a constant interval in an in-plane direction, and a dielectric material 1832 fills the holes in the amorphous silicon layer 1831.

Alternatively, the air may be used in place of the dielectric materials 1812 and 1832.

The structure layers forming the multilayer reflective film may have the same thickness, or different thicknesses.

Between two adjacent structure layers forming the multilayer reflective film, there is provided, in constant with the two adjacent structure layers, a layer having a refractive index lower than that of a high refractive index material forming the high refractive index region. Examples of the low refractive index layer include an oxide, a nitride, or an oxynitride of silicon, gallium, aluminum, and indium which are the dielectric material. In FIG. 1, a low refractive index layer 182 is provided between two structure layers 181 and 183 and in constant with the structure layer 181 and the structure layer 183.

A dielectric layer 19 is provided on the multilayer reflective film 18. The dielectric layer 19 may be formed of the dielectric material which is used to form the low refractive index layer 182.

The semiconductor light emitting structure 16 may include a current constriction structure. The current constriction structure constricts the current passing through the semiconductor laser in order to reduce a reactive current which diffuses within the semiconductor laser, and defines a light emitting region including the active layer 163, or an aperture.

In this embodiment, a current constriction layer 20 is provided in the semiconductor light emitting structure 16. The current constriction layer 20 can be formed by, for example, proton implantation.

In the above structure, the current constriction layer 20, including a part of the first clad layer 161, may be processed into a mesa structure to obtain a frusto-conical shape or a truncated pyramid shape as illustrated in FIG. 1.

The semiconductor light emitting device 10 further comprises a pair of electrodes to apply the current to the semiconductor light emitting structure 16. An electrically insulating layer 21 is formed to cover the peripheral portion of the current constriction layer 20 and the surface of the first clad layer 161 except part of the surface of the current constriction layer 20 and the surface of an uppermost layer 165 of the semiconductor light emitting structure 16. One electrode 221 of the pair of electrodes is connected to the first clad layer 161 through the electrically insulating layer 21. The electrode 221 may be annular.

The other electrode 222 is formed to cover the peripheral portions of the multilayer reflective film 18, the dielectric layer 19, and the current constriction layer 20, as well as a part of the surface of the current constriction layer 20 which is exposed from the electrically insulating layer 21 and the surface of the uppermost layer 165 of the semiconductor light emitting structure 16. In other words, the uppermost layer 165 of the semiconductor light emitting structure 16 serves as a contact layer with respect to the electrode 222. The electrode 222 may be formed of a metal layer. It is a matter of course that this metal layer also serves as the other electrode in the pair of electrodes. In addition, the metal layer further enhances a reflectance of the second light reflecting structure which includes the multilayer reflective film 18. The reflectance of the second light reflecting structure including the multilayer reflective film 18 can reach almost 99.9% reflectance by further providing the metal layer 222. The metal layer 222 can be selected according to light emitted from the laser. For example, in a case where the emitted light is a visible light, the metal layer 222 may be formed of silver. In a case where the emitted light is a near-infrared light, the metal layer 222 may be formed of gold, aluminum, or copper.

In this way, the light generated in the active layer 163 is more securely output from the substrate 11 by providing the metal layer 222 as the uppermost layer of the second light reflecting structure.

The light generated in the active layer 163 is amplified while moving reciprocally between the two light reflecting structures, and passes through the first light reflecting structure 13 and emitted in a direction perpendicular to the surface of the substrate 11. In this case, a semiconductor material having a band-gap energy larger than that of the semiconductor material forming the active layer is used as the semiconductor material of the substrate 11 in order to allow the light generated in the active layer 163 to pass through the substrate 11. For example, in a case where the active layer is formed of a group III-V compound semiconductor or a group II-VI compound semiconductor, the substrate 11 may be formed of silicon.

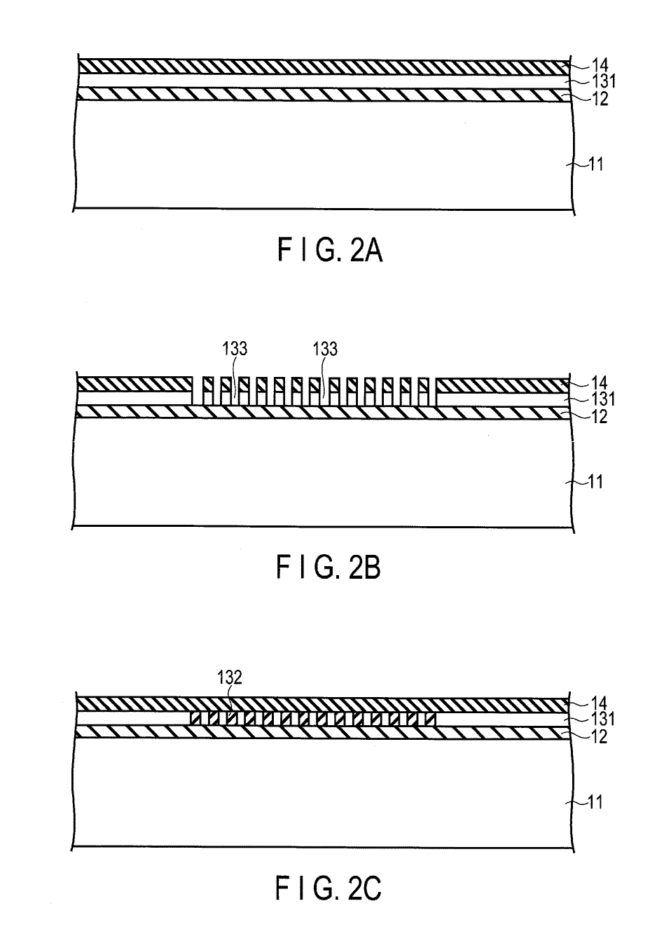

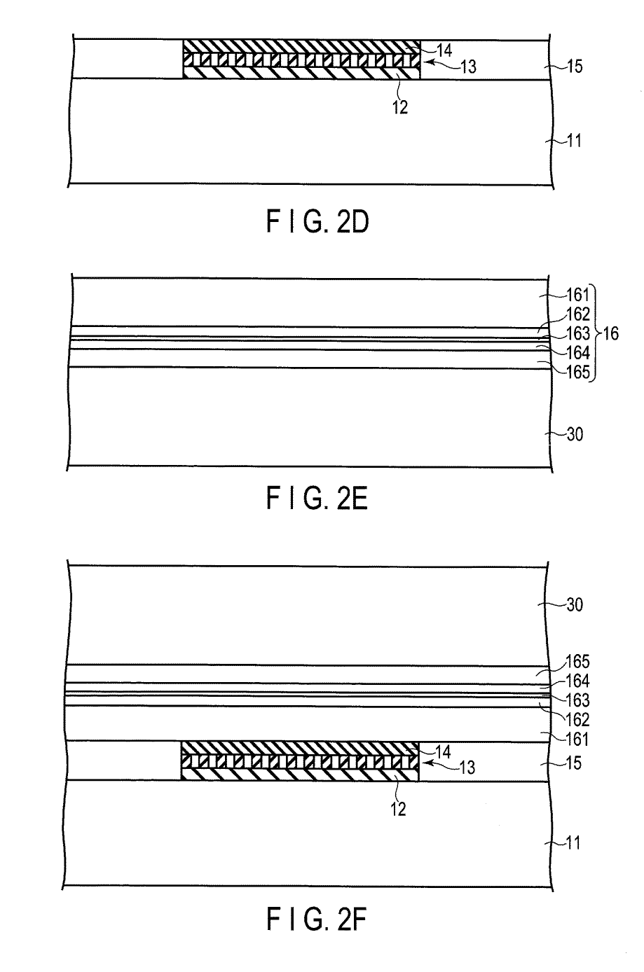

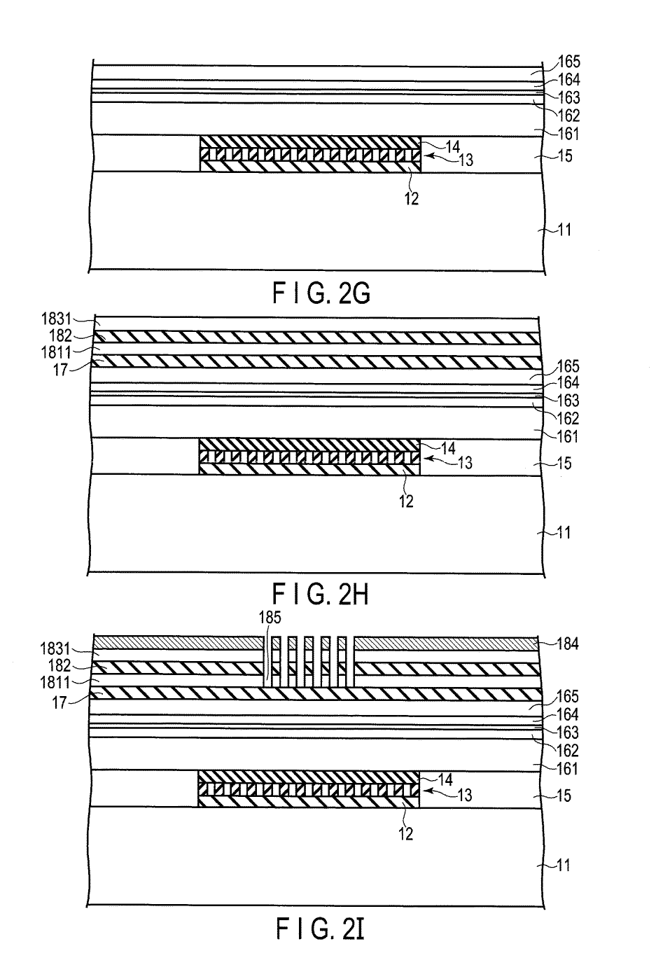

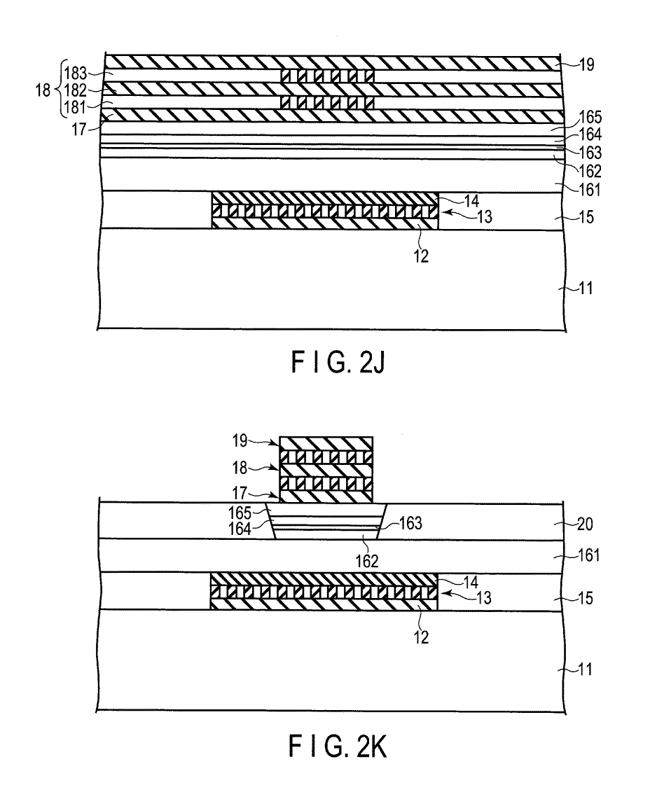

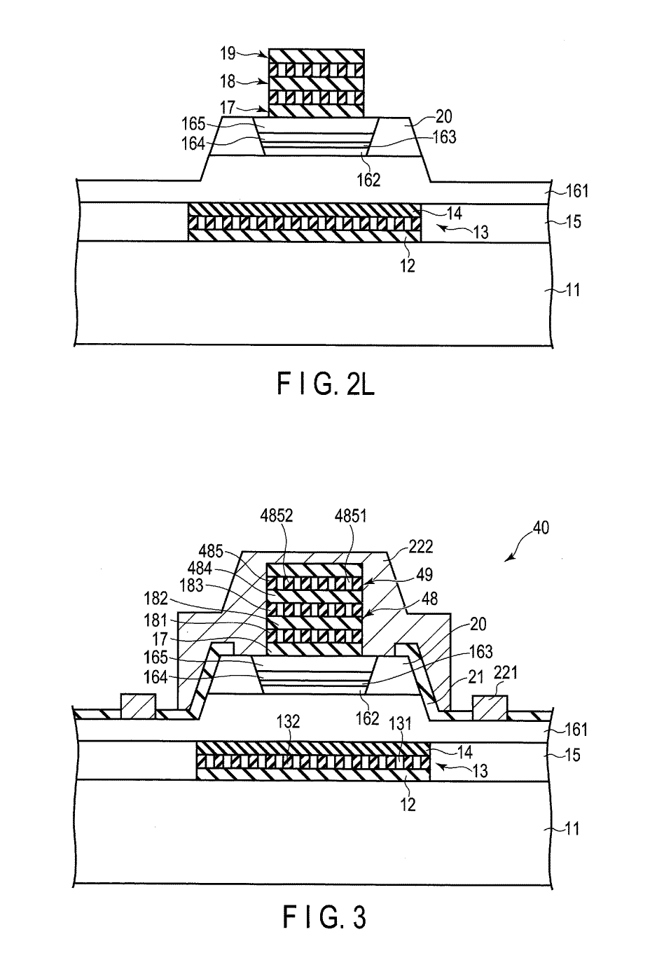

Next, an exemplary method of manufacturing the semiconductor light emitting device 10 (according to the first embodiment) illustrated in FIG. 1 will be described with reference to FIGS. 2A, 2B, 2C, 2D, 2E, 2F, 2G, 2H, 2I, 2J, 2K and 2L (hereinafter, referred to as FIGS. 2A to 2L).

The method is an example of a method of manufacturing the semiconductor laser device illustrated in FIG. 1 in which the substrate 11 is a dissimilar substrate formed of a semiconductor material dissimilar to that of the semiconductor light emitting structure 16.

First, as illustrated in FIG. 2A, the dielectric layer (for example, silicon oxide layer) 12, the amorphous silicon layer 131, and the low refractive index layer (for example, silicon oxide layer) 14 are formed on the dissimilar substrate 11 such as a silicon substrate.

Next, the silicon oxide layer 14 is patterned, and the amorphous silicon layer 131 is subjected to a wet or dry etching using the patterned silicon oxide layer 14 as a mask to form openings 133 which are spaced apart from each other at a constant interval in the amorphous silicon layer 131 (FIG. 2B).

Thereafter, without removing the silicon oxide layer 14 used as the mask, the dielectric layer is formed on the entire surface of the silicon oxide layer 14 including the inside of the openings 133 of the amorphous silicon layer 131. Then, the formed dielectric layer is removed, and the surface of the silicon oxide layer 14 is planarized by CMP (FIG. 2C). Subsequently, the silicon oxide layer 14, the amorphous silicon layer 131, and the underlying dielectric layer 12 except the portion corresponding to the structure layer 13 are sequentially removed by etching to expose the surface of the substrate 11. Thereafter, a semiconductor (for example, the amorphous silicon 15) similar to that of the substrate 11 is deposited on the surface of the silicon oxide layer 14 and the exposed substrate 11. Then, the amorphous silicon 15 is planarized by CMP until the surface of the silicon oxide layer 14 is exposed (FIG. 2D). The above semiconductor structure including the structure layer 13 will be referred to as a first semiconductor structure.

On the other hand, as illustrated in FIG. 2E, the second clad layer 165, the second light confinement layer 164, the active layer 163, the first light confinement layer 162, and the first clad layer (also serving as the contact layer) are laminated on the similar substrate (for example, group III-V compound semiconductor substrate) 30 to form the semiconductor light emitting structure 16. The semiconductor light emitting structure 16 is formed of a group III-V compound semiconductor for example. In this case, it is desirable that the first clad layer 161 and the second clad layer 165 be formed of InP of n or p type. Thus, the semiconductor light emitting structure 16 including the active layer is obtained, and the semiconductor structure including the semiconductor light emitting structure 16 will be referred to as a second semiconductor structure.

Next, the first semiconductor structure and the second semiconductor structure are bonded to each other such that the surface including the silicon oxide layer 14 in the first semiconductor structure faces the first clad layer 161 in the second semiconductor structure. When being formed of InP, the first clad layer 161 can be directly bonded with the amorphous silicon layer 15 (FIG. 2F). The structure thus obtained will be referred to as a third semiconductor structure.

Next, the similar substrate 30 is removed from the third semiconductor structure by mechanical polishing or wet etching. The surface (the second clad layer 165) of the semiconductor light emitting structure 16 is thus exposed (FIG. 2G).

Next, the low refractive index layer 17 (for example, silicon oxide layer), the amorphous silicon layer 1811, the low refractive index layer (for example, silicon oxide layer) 182, and the amorphous silicon layer 1831 are formed on the exposed second clad layer 165 (FIG. 2H).

Next, a resist layer 184 is formed and patterned on the amorphous silicon layer 1831, and the amorphous silicon layer 1831, the silicon oxide layer 182, and the amorphous silicon layer 1811 are subjected to dry etching (for example, using sulfur hexafluoride gas) to form openings 185 spaced apart from each other in a predetermined period in these three layers 1831, 182, and 1811 (FIG. 2I).

Next, the resist layer 184 is removed, and the dielectric layer (for example, silicon oxide layer) 19 is formed on the entire surface of the amorphous silicon layer 1831 including the inside of the openings 185. Then, the surface of the formed dielectric layer 19 is planarized by CMP. Thus, on the semiconductor light emitting structure 16, the multilayer reflective film 18 where the low refractive index layer is disposed between the two structure layers whose refractive indexes are periodically changed (FIG. 2J).

Next, the dielectric layer 19 and the laminate underlying therebelow except the portions corresponding to the structure layer 13 and the multilayer reflective film 18 are sequentially removed by etching to expose a part of the surface of the second clad layer 165. Then, ion implantation is conducted on the current constriction formation layer. The ion implantation is, for example, a proton implantation. Through the ion implantation, the current constriction layer 20 is formed in the semiconductor light emitting structure 16 (FIG. 2K). The current constriction layer 20 may be annular.

Then, the current constriction layer 20 is processed into a mesa structure to obtain a frusto-conical shape (FIG. 2L).

Thereafter, the electrically insulating layer 21 and the electrodes 221 and 222 are formed to manufacture the semiconductor light emitting device 10 having the structure illustrated in FIG. 1. Naturally, the semiconductor light emitting structure 16 defined by the current constriction layer 20 and the second and first light reflecting structures 18 and 13 constitute an optical resonator or cavity.

According to the manufacturing method described with reference to FIGS. 2A to 2L, the completed semiconductor light emitting device includes the semiconductor light emitting structure 16 formed of a group III-V compound semiconductor on the dissimilar substrate (for example, the silicon substrate) 11. However, since the semiconductor light emitting structure 16 is formed on the similar substrate 30, a lattice matching is achieved. Therefore, there is no need to pay attention on the lattice mismatching such as a case where the group III-V compound semiconductor layer is grown on the dissimilar substrate. In other words, according to the method, there is no need to perform a heteroepitaxial growth.

Now, examples of group III-V compound semiconductor constituting the semiconductor light emitting structure, including active layer, as well as the base material of the high refractive index region of the structure layer and the substrate will be described below:

<InP-Based Device (Part 1)>

Active layer: Multi-quantum well structure of InGaAsP/InGaAsP of which the composition ratio of In is different

First and second light confinement layers: InGaAsP or InP

First and second clad layers: InGaAsP or InP

First and second contact layers: InP or InGaAs

Light emission wavelength band: 1.2 to 1.7 μm

Base material of the high refractive index region of the structure layer: Amorphous silicon or InP

Substrate: InP

<InP-Based Device (Part 2)>

Active layer: Multi-quantum well structure of InGaAlAs/InGaAlAs of which the composition ratio of In is different

First and second light confinement layers: InGaAlAs, InGaAsP, or InP

First and second clad layers: InGaAlAs or InP

First and second contact layers: InP or InGaAs

Light emission wavelength band: 1.3 μm

Base material of the high refractive index region of the structure layer: Amorphous silicon or InP

Substrate: InP

<GaAs-Based Device (Part 1)>

Active layer: Multi-quantum well structure of InGaAs/GaAs

First and second light confinement layers: AlGaAs or GaAs

First and second clad layers: AlGaAs or GaAs

First and second contact layers: GaAs

Light emission wavelength band: 0.9 to 1.15 μm

Base material of the high refractive index region of the structure layer: GaAs

Substrate: GaAs

<GaAs-Based Device (Part 2)>

Active layer: Multi-quantum well structure of AlGaAs/GaAs

First and second light confinement layers: AlGaAs or GaAs

First and second clad layers: AlGaAs or GaAs

First and second contact layers: GaAs

Light emission wavelength band: 0.62 to 0.87 μm

Base material of the high refractive index region of the structure layer: AlGaAs

Substrate: GaAs

<GaAs-Based Device (Part 3)>

Active layer: Multi-quantum well structure of AlGaInP/GaAs

First and second light confinement layers: AlGaInP, AlGaAs, GaAs

First and second clad layers: AlGaInP or GaAs

First and second contact layers: GaAs

Light emission wavelength band: 0.54 to 0.7 μm

Base material of the high refractive index region of the structure layer: AlGaAs

Substrate: GaAs

<GaN-Based Device>

Active layer: Multi-quantum well structure of InGaN/AlGaN

First and second light confinement layers: AlGaN or GaN

First and second clad layers: AlGaN or GaN

First and second contact layers: GaN or InGaN

Light emission wavelength band: 0.3 to 0.6 μm

Base material of the high refractive index region of the structure layer: GaN or AlGaN

Substrate: Sapphire or GaAs

The semiconductor layer may be formed of a ZnSe-based semiconductor (for example, a group II-VI compound semiconductor such as CdZnSSe).

In addition, examples of the metal material for forming the electrode will be described below.

<InP-Based Semiconductor Layer>

p-electrode: Three-layer structure of Ti/Pt/Au, Two-layer structure of An/Au, and the like

n-electrode: Three-layer structure of Ti/Pt/Au

<GaAs-Based Semiconductor Layer>

p-electrode: Three-layer structure of Ti/Pt/Au

n-electrode: Three-layer structure of AuGe/Ni/Au

The thicknesses of the amorphous silicon layers 1811 and 1831 are, for example, 0.2 μm to 0.5 μm.

The thicknesses of the first and second contact layers 161 and 165 forming the semiconductor light emitting structure 16 are, for example, 0.2 μm to 1.5 μm respectively. The thicknesses of the first and second clad layers 161 and 165 are, for example, 0.1 μm to 0.5 μm respectively. The thicknesses of the first and second light confinement layers 162 and 164 are, for example, 0.05 μm to 0.2 μm respectively. The thickness of the active layer 163 is, for example, 0.05 μm to 0.2 μm. Further, the diameter of the aperture defined by the current constriction layer 20 is, for example, 5 μm to 20 μm.

The thicknesses of the low refractive index layer 14 provided between the structure layer 13 and the first contact layer 161, and the low refractive index layer 17 provided between the second contact layer 165 and the multilayer reflective film 18 are, for example, 150 nm to 200 nm respectively.

FIG. 3 is a schematic cross-sectional view of a semiconductor light emitting device 40 according to a second embodiment.

The semiconductor light emitting device 40 illustrated in FIG. 3 has the same structure as that of the semiconductor light emitting device 10 illustrated in FIG. 1 except that there are provided a multilayer reflective film 48 which further includes a low refractive index layer 484 and a structure layer 485 on the structure layer 183, and a dielectric layer 49 on the multilayer reflective film 48.

In FIG. 3, the multilayer reflective film 48 forming the second light reflecting structure includes three structure layers 181, 183, and 485 which are disposed apart from each other and have the refractive indexes which are periodically changed. The structure layer 485 may be constituted similarly to the structure layers 181 and 183. In other words, the structure layer 485 is configured by a high refractive index region which has a relatively-high refractive index and a low refractive index region which has a relatively-low refractive index, both of which are periodically disposed two-dimensionally. The structure layers each can be constituted by a photonic crystal thin film. In other words, the structure layer 485 includes a high refractive index layer made of a high refractive index material as a base material, and a dielectric material having a refractive index lower than that of the base material is buried at a constant interval in the base material. Examples of the base material include amorphous silicon, InP, GaAs, AlGaAs, GaN, and AlGaN, and examples of the dielectric material include an oxide, a nitride, or an oxynitride of silicon, gallium, aluminum, and indium. In FIG. 3, in the amorphous silicon forming a base material 4851, a plurality of holes are formed at a constant interval in an in-plane direction, and a dielectric material 4852 fills the holes in the amorphous silicon layer 4851. Alternatively, the air may be used in place of the dielectric material 4852.

A layer having a refractive index lower than a high refractive index material forming the high refractive index region is provided between every two adjacent structure layers and in contact with two adjacent structure layers. Examples of the low refractive index layer include an oxide, a nitride, or an oxynitride of silicon, gallium, aluminum, and indium which are the dielectric material. In FIG. 3, the low refractive index layer 182 is provided between the structure layers 181 and 183 and in contact with the structure layer 181 and the structure layer 183. In addition, the low refractive index layer 484 is provided between the structure layers 183 and 485 and in contact with the structure layer 183 and the structure layer 485.

The multilayer reflective film 48 illustrated in FIG. 3 further includes the low refractive index layer 484 and the structure layer 485 in addition to the multilayer reflective film 18 illustrated in FIG. 1, so that the reflectance can be enhanced.

A thickness d and a refractive index n of the low refractive index layer included in the multilayer reflective film constituting the second light reflecting structure, and an emission wavelength λ of the semiconductor light emitting device may be configured to satisfy the following relation:

d<(¼n)·λ (1)

The above relation (1) defines a preferable condition under which prevented is resonance and/or interference of the light, occurring between two adjacent structure layers when the distance between the two adjacent structures, between which the low refractive index layer is interposed, or the thickness of the low refractive index layer, becomes too large.

The thickness d and the refractive index n of the low refractive index layer included in the multilayer reflective film constituting the second light reflecting structure, and the emission wavelength λ of the semiconductor light emitting device may be configured to satisfy the following relation:

exp(−2πnd/λ)<0.5 (2)

The above relation (2) defines a condition which the distance between two adjacent structure layers, between which the low refractive index layer is interposed, or the thickness of the low refractive index layer, preferably have in order to prevent light confinement mode inside the structure layers, necessary for the structure layers to function as a multilayer reflective film, from ceasing to exist when the distance of the two structure layers, or the thickness of the low refractive index layer, becomes too small.

In addition, relation (2) is also a condition for attenuating the undesirable light excessively leaking to the low refractive index layer to be half or less.

In this case, the refractive index and the thickness of the structure layer also somewhat affect leakage amount of the light depending on their relation with the emission wavelength. However, the multilayer reflective film made of a combination of amorphous silicon and a silicon oxide satisfying the above relation (2) outperforms a single-layer reflective film consisting of one structure layer.

The multilayer reflective film included in the semiconductor light emitting device which is configured to satisfy the above relation (1) and/or (2) is enhanced in a reflectance of the light and a wavelength bandwidth of the reflected light.

The thickness of the low refractive index layer included in the multilayer reflective film is, for example, 150 nm to 200 nm.

In the case of a multilayer reflective film in which a low refractive index layer having a thickness of 250 nm or more is provided between two structure layers in contact with them, when, for example, the light having a wavelength band near 1.3 μm is incident perpendicular to the multilayer reflective film, the reflectance may be largely reduced in the narrow band near the reflected light having a wavelength band of 1.3 μm, due presumably to interference or resonance.

In a multilayer reflective film in which a low refractive index layer having a thickness of less than 150 nm is interposed between two structure layers and in contact with them, the reflectance is reduced compared to a single-layer reflective film constituted by one structure layer for example.

The thickness of the structure layer included in the multilayer reflective film is, for example, 360 nm to 410 nm.

A multilayer reflective film in which a low refractive index layer is interposed between two structure layers having different thicknesses and in contact with them may be improved in the reflectance compared to a multilayer reflective film in which a low refractive index layer is interposed between the structure layers having the same thickness and in contact with them for example.

Hereinafter, experimental examples will be described.

### EXAMPLE 1

A structure layer having a thickness of 400 nm, constituted by a silicon oxide region and an amorphous silicon region disposed such that the refractive index was periodically changed in the in-phase direction, was manufactured and used as a reflective film.

### EXAMPLE 2

A multilayer reflective film was manufactured in which a silicon oxide layer having a thickness of 200 nm was provided between the structure layers having thicknesses of 360 nm and 410 nm and in contact with them, each of which was configured by a silicon oxide region and an amorphous silicon region disposed such that the refractive index was periodically changed in the in-plane direction.

### EXAMPLE 3

A multilayer reflective film was manufactured such that a silicon oxide layer having a thickness of 200 nm was interposed between two structure layers having thicknesses of 360 nm and 410 nm as in Example 2, and a silicon oxide layer having a thickness of 200 nm was interposed between, and in contact with, the above structure layer having a thickness of 410 nm and a structure layer having a thickness of 390 nm which is constituted by a silicon oxide region and an amorphous silicon region disposed such that the refractive index was periodically changed in the in-plane direction.

[Evaluation]

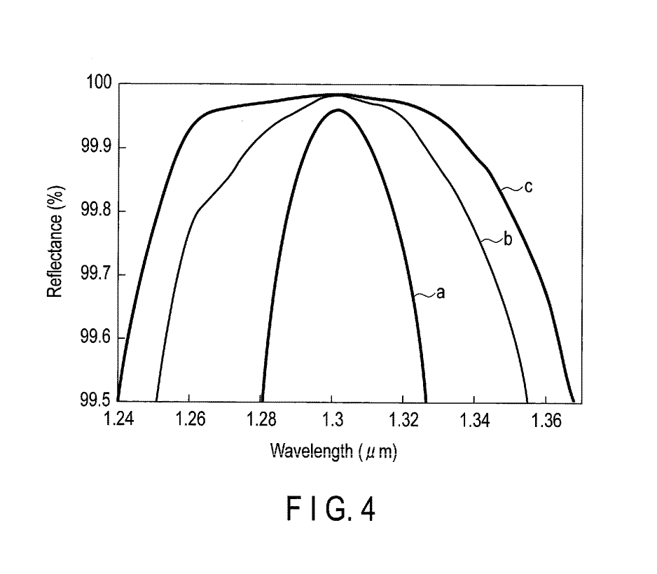

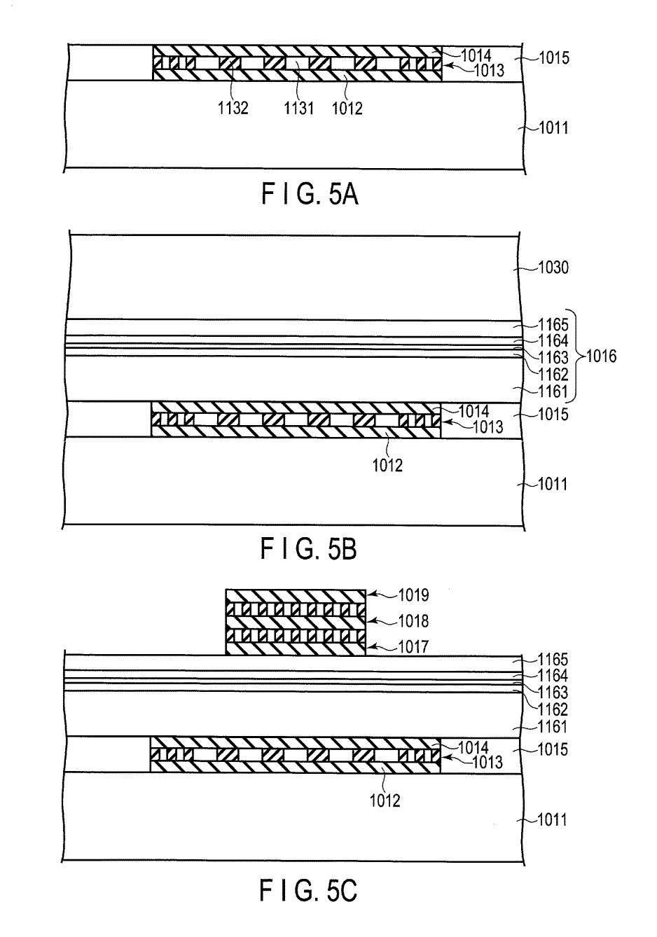

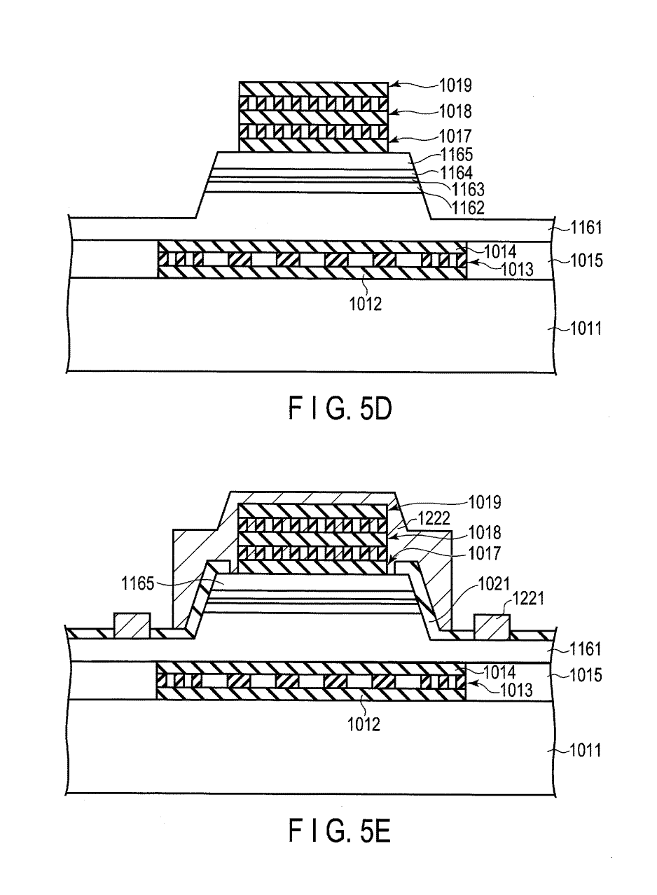

According to a finite difference time domain simulation, the light near a wavelength band of 1.3 μm incident perpendicular to the reflective film of Examples 1 to 3 was analyzed as to its reflection. The results are shown in FIG. 4.

[Results]

The reflective film of Example 1 shows 99.9% or more reflectance in a wavelength bandwidth of about 0.02 μm (20 nm), and shows 99.5% or more reflectance in a wavelength bandwidth of about 0.045 μm (45 nm), as shown by curve a in FIG. 4

The reflective film of Example 2 shows 99.9% or more reflectance in a wavelength bandwidth of about 0.05 μm (50 nm), and shows 99.5% or more reflectance in a wavelength bandwidth of about 0.1 μm (100 nm), as shown by curve b in FIG. 4

The reflective film of Example 3 shows 99.9% or more reflectance in a wavelength bandwidth of about 0.08 μm (80 nm), and shows 99.5% or more reflectance in a wavelength bandwidth of about 0.125 μm (125 nm), as shown by curve c in FIG. 4

According to the above experimental examples, it has been confirmed that the multilayer reflective film is increased in the reflectance and in the wavelength bandwidth of the reflected light as the number of layers is increased. The semiconductor light emitting device including such a multilayer reflective film has tolerance with respect to a deviation in wavelength of the light generated in the active layer.

Incidentally, it is possible to manufacture a semiconductor light receiving device which includes the multilayer reflective film according to some of the embodiments with reference to the method of manufacturing the semiconductor light emitting device according to the first embodiment described referring to FIGS. 2A to 2L. An exemplary method of manufacturing such a semiconductor light receiving device will be described below.

As illustrated in FIG. 5A, a structure layer 1013 and a low refractive index layer 1014 in which the refractive index changes are formed on the lower side of the light receiving device on a dissimilar substrate (for example, the silicon substrate) 1011 like the substrate 11 illustrated in FIG. 1, with reference to the method described referring to FIGS. 2A, 2B, 2C and 2D. The structure layer 1013 is formed on a dielectric layer 1012, the low refractive index layer 1014 is formed on the structure layer 1013, and the laminate of the dielectric layer 1012, the structure layer 1013, and the low refractive index layer 1014 is surrounded by an amorphous silicon layer 1015. In the structure layer 1013, a high refractive index region 1131 made of an amorphous silicon and a low refractive index region 1132 made of a dielectric material buried in holes provided in the amorphous silicon are disposed two-dimensionally. The structure layer 1013 is a diffraction grating. The light from the substrate 1011 is incident onto the structure layer 1013 of the light receiving device. The semiconductor structure (the semiconductor structure illustrated in FIG. 5A) thus obtained is referred to as a semiconductor structure A.

Next, a second clad layer 1165, a second light confinement layer 1164, an active layer 1163, a first light confinement layer 1162, a first clad layer (also serving as a contact layer) 1161 are laminated on a similar substrate (for example, a group III-V compound semiconductor substrate) 1030 with reference to the method described referring to FIG. 2E so as to form a semiconductor light emitting structure 1016. Thus, a semiconductor structure (semiconductor structure B) which has the semiconductor light emitting structure 1016 including the active layer is obtained. Next, the semiconductor structure A and the semiconductor structure B are bonded such that the surface including the low refractive index layer 1014 in the semiconductor structure A faces the first clad layer 1161 in the semiconductor structure B. When being formed of InP, the first clad layer 1161 can be directly bonded with the amorphous silicon layer 1015. The structure thus obtained will be referring to as a semiconductor structure C (FIG. 5B).

Next, the similar substrate 1030 is removed from the semiconductor structure C by mechanical polishing or wet etching to expose the surface of the semiconductor light emitting structure 1016 (an uppermost layer 1165). Then, a low refractive index layer 1017, a multilayer reflective film 1018, and a dielectric layer 1019 are fabricated on the uppermost layer 1165 with reference to the method described referring to FIGS. 2H, 2I, 2J and 2K (FIG. 50).

Then, the semiconductor layers of the light receiving device are processed into a mesa structured to obtain a frusto-conical shape with reference to the method described referring to FIG. 2L (FIG. 50).

Finally, an electrically insulating film 1021 and electrodes 1221 and 1222 are formed in the light receiving device structure with reference to the method described referring to FIG. 2L. Thus, the semiconductor light receiving device is manufactured (FIG. 5E).

As can be seen from the above description, the semiconductor light receiving device includes the multilayer reflective film like that included in the semiconductor light emitting device according to the embodiment. Therefore, it is possible to manufacture the semiconductor light emitting device according to the embodiment simultaneously with the semiconductor light receiving device on the same substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light emitting device, comprising:
a substrate;
a semiconductor light emitting structure including an active layer;
a first light reflecting structure disposed between the substrate and the semiconductor light emitting structure;
a second light reflecting structure disposed on an upper side of the semiconductor light emitting structure; and
a pair of electrodes applying a current to the semiconductor light emitting structure,
wherein at least one of the first light reflecting structure and the second light reflecting structure is a multilayer reflective film including a plurality of structure layers, each structure layer including a high refractive index region and a low refractive index region which are disposed such that a refractive index of the structure layer is periodically changed, and a low refractive index layer disposed between two adjacent structure layers.

2. The semiconductor light emitting device according to claim 1,
wherein a thickness d of the low refractive index layer, a refractive index n of the low refractive index layer, and an emission wavelength λ of the semiconductor light emitting device satisfy the following relation:
d<(¼n)·λ (1).

3. The semiconductor light emitting device according to claim 1,
wherein a thickness d of the low refractive index layer, a refractive index n of the low refractive index layer, and an emission wavelength λ of the semiconductor light emitting device satisfy the following relation:
exp(−2πnd/λ)<0.5 (2).

4. The semiconductor light emitting device according to claim 2,
wherein a thickness d of the low refractive index layer, a refractive index n of the low refractive index layer, and an emission wavelength λ of the semiconductor light emitting device satisfy the following relation:
exp(−2πnd/λ)<0.5 (2).

5. The semiconductor light emitting device according to claim 1, further comprising a first dielectric layer disposed between the substrate and the first light reflecting structure, and/or a second dielectric layer disposed between the second light reflecting structure and the electrode.

6. The semiconductor light emitting device according to claim 1,
wherein the second light reflecting structure includes a metal layer that serves as one of the pair of electrodes.

7. The semiconductor light emitting device according to claim 1,
wherein the structure layers are different in thickness from each other.

8. The semiconductor light emitting device according to claim 1,
wherein the low refractive index region is made of silicon oxide or air, and the high refractive index region is made of silicon.

9. The semiconductor light emitting device according to claim 1,
wherein the low refractive index layer is made of silicon oxide.

10. The semiconductor light emitting device according to claim 1,
wherein the structure layer is constituted by a photonic crystal.

11. The semiconductor light emitting device according to claim 1,
wherein the first light reflecting structure is made of a single-layer reflective film constituted by one structure layer, the second light reflecting structure is made of the multilayer reflective film, and the structure layer is constituted by the high refractive index region and the low refractive index region disposed such that a refractive index of the structure layer is periodically changed.

12. The semiconductor light emitting device according to claim 1,
wherein the semiconductor light emitting structure comprises a group III-V compound semiconductor.

13. The semiconductor light emitting device according to claim 1,
wherein the substrate is formed of a semiconductor material having a band-gap energy larger than that of a semiconductor material of the active layer.

14. The semiconductor light emitting device according to claim 1,
wherein the substrate is a dissimilar substrate formed of a semiconductor material dissimilar to that of the semiconductor light emitting structure.

15. The semiconductor light emitting device according to claim 1,
wherein the substrate is a silicon substrate.

16. The semiconductor light emitting device according to claim 1,
wherein the first light reflecting structure is surrounded by a semiconductor formed on the substrate and made of a semiconductor similar to that of the substrate, and a surface of the first light reflecting structure is included in a plane including a surface of the similar semiconductor or is placed below the plane.
